(19) United States
(12) Patent Application Publication
(10) Pub. No.: US 2026/0240055 A1
(43) Pub. Date: Aug. 13, 2026

(54) Semiconductor Device and Manufacturing Method for Same

(71) Applicant: Hitachi, Ltd., Chiyoda-ku, Tokyo (JP)

(72) Inventors: Hiroyuki MATSUSHIMA, Tokyo (JP); Haruka SHIMIZU, Tokyo (JP)

(21) Appl. No.: 19/151,686

(22) PCT Filed: Nov. 30, 2023
(86) PCT No.: PCT/JP2023/042897

§ 371 Date: Jul. 29, 2025

(30) Foreign Application Priority Data
Feb. 21, 2023 (JP) 2023-025416

(51) Int. Cl. H10W 90/00; H10W 72/00; H10W 74/01

(52) U.S. Cl. CPC H10W 90/764; H10W 72/016; H10W 72/881; H10W 90/724; H10W 74/014

(57) ABSTRACT

The performance is improved for a semiconductor device which is a semiconductor chip having an exposed terminal and which comprises a semiconductor substrate provided with a semiconductor element. A semiconductor device having the following is used as a means for accomplishing this: a first main surface; a second main surface on an opposite side from the first main surface; a semiconductor substrate provided with a semiconductor element; a first terminal which is connected, via an electrically conductive first bonding material, to a first electrode that is disposed in contact with the first main surface; a second terminal which is insulated from the first terminal and is connected, via an electrically conductive second bonding material, to a second electrode that is disposed in contact with the second main surface; an insulating material that seals the semiconductor substrate and a part of each of the first terminal and the second terminal; a third main surface which is positioned on the first bonding material side with regard to the semiconductor substrate and on which the first terminal and second terminal are exposed; and a fourth main surface on an opposite side from the third main surface. The second terminal is led out to the third main surface side by a lead-out electrode that resides at a distance from a multilayered structure that contains the semiconductor substrate, the first electrode, and the first bonding material. The interval between the first terminal and the second terminal is insulated by the insulating material.

### TECHNICAL FIELD

The present invention can be used for a semiconductor device and a manufacturing method for the same.

### BACKGROUND ART

In recent years, power conversion devices using semiconductor module devices on which SiC (silicon carbide) power semiconductor chips are mounted have started to be put on the market. A wide bandgap power semiconductor represented by SiC has a conduction loss smaller than that of a conventional Si (silicon) power semiconductor, and thus a small semiconductor module using a semiconductor chip having a small size can be produced. However, in SiC in which the quality and process maturity of a substrate are lower than those of Si, the yield of the semiconductor chip is low. Thus, it is required to remove a defective chip before modularization, by enhancing an inspection for each semiconductor chip.

As a structure of the semiconductor chip, it is conceivable that an electrode is provided on each of the front surface and the back surface on the opposite side. Regarding this, PTL 1 (JP 2007-184553 A) discloses that a through electrode electrically connected to a metal film (electrode) on the back surface side is formed in a through-hole penetrating from the front surface to the back surface of a semiconductor substrate.

### CITATION LIST

### Patent Literature

PTL 1: JP 2007-184553 A

### SUMMARY OF INVENTION

### Technical Problem

When a characteristic inspection by energization is performed for each semiconductor chip, it is necessary to prevent discharge. In a case where electrodes are provided on the front surface and the back surface of the semiconductor chip, it is necessary to release the terminals on both the surfaces, and the restriction for preventing discharge increases. In addition, since it is difficult to bring a probe into contact with a small semiconductor chip, it is conceivable to perform an inspection after modularization by connecting a plurality of chips in parallel. However, due to the defect of one semiconductor chip, a plurality of other semiconductor chips connected in parallel are also treated as defects, and the yield in manufacturing of the module decreases, which causes an increase in cost. These problems are particularly noticeable in a SiC chip having a size smaller than that of a Si chip.

In addition, in a case where there is an electrode on each of the front surface and the back surface of the semiconductor chip, it is necessary to connect a conductor such as a bonding wire having a relatively cross-sectional area to the electrode on the front surface side. This causes an increase in resistance of a semiconductor device, an increase in size of the semiconductor device, and an increase in manufacturing cost of the semiconductor device.

Furthermore, in such a semiconductor chip, since heat is likely to rise on the front surface side to which the bonding wire is connected, it is conceivable to provide a mechanism for cooling both the front surface and the back surface. However, providing the cooling mechanisms on both sides leads to an increase in size of the semiconductor device and an increase in manufacturing cost.

The above-described and other objects and novel features of the present invention will become apparent from the description of the present specification and the accompanying drawings.

### Solution to Problem

An outline of representative embodiments disclosed in the present application will be briefly described as follows.

According to a representative embodiment, a semiconductor device includes: a semiconductor substrate including a first main surface, a second main surface opposite to the first main surface, and a semiconductor element; a first terminal connected to a first electrode provided in contact with the first main surface via a first bonding material having conductivity; a second terminal connected to a second electrode provided in contact with the second main surface via a second bonding material having conductivity, the second terminal being insulated from the first terminal; an insulating material that seals the semiconductor substrate and a part of each of the first terminal and the second terminal; a third main surface located on the first bonding material side with respect to the semiconductor substrate, the first terminal and the second terminal being exposed on the third main surface; and a fourth main surface opposite to the third main surface. The second terminal is extracted to the third main surface side by an extraction electrode spaced from a stacked body including the semiconductor substrate, the first electrode, and the first bonding material, and the first terminal and the second terminal are insulated from each other by the insulating material.

According to another representative embodiment, a manufacturing method for a semiconductor device includes: (a) a step of preparing a semiconductor substrate including a first main surface, a second main surface opposite to the first main surface, and a semiconductor element, a first electrode being in contact with the first main surface, and a second electrode being in contact with the second main surface; (b) a step of connecting a first conductor to the first electrode via a first bonding material having conductivity; (c) a step of preparing a second conductor having a first protrusion on a surface; (d) a step of spacing a stacked body including the semiconductor substrate and the first electrode from the first protrusion and connecting the second electrode to the surface of the second conductor via a second bonding material having conductivity; and (e) a step of sealing the semiconductor substrate, the first conductor, and the second conductor with an insulating material after the steps (a) to (d). Here, the semiconductor device includes a third main surface on which a first terminal made of the first conductor and a second terminal made of the second conductor are exposed, and a fourth main surface opposite to the third main surface. The third main surface is located on the first bonding material side with respect to the semiconductor substrate. The first terminal and the second terminal are insulated from each other, and the second terminal is extracted toward the third main surface by the first protrusion.

### Advantageous Effects of Invention

According to the representative embodiment, it is possible to improve the performance of the semiconductor device. In particular, it is possible to reduce the size of the semiconductor device.

According to another representative embodiment, it is possible to improve the yield of the semiconductor device. In particular, it is possible to inspect a semiconductor chip alone.

### BRIEF DESCRIPTION OF DRAWINGS

FIG. 1 is a plan view illustrating a semiconductor device according to Embodiment 1.

FIG. 2 is a cross-sectional view taken along line A-A in FIG. 1.

FIG. 3 is a cross-sectional view illustrating a semiconductor module on which the semiconductor device according to Embodiment 1 is mounted.

FIG. 4 is a flowchart illustrating a manufacturing process of the semiconductor device according to Embodiment 1.

FIG. 5 is a cross-sectional view during the manufacturing process of the semiconductor device according to Embodiment 1.

FIG. 6 is a plan view illustrating an example of a layout of conductors used for manufacturing the semiconductor device according to Embodiment 1.

FIG. 7 is a cross-sectional view during the manufacturing process of the semiconductor device subsequent to FIG. 5.

FIG. 8 is a cross-sectional view during the manufacturing process of the semiconductor device subsequent to FIG. 7.

FIG. 9 is a cross-sectional view during the manufacturing process of the semiconductor device subsequent to FIG. 8.

FIG. 10 is a cross-sectional view during the manufacturing process of the semiconductor device subsequent to FIG. 9.

FIG. 11 is a cross-sectional view during the manufacturing process of the semiconductor device subsequent to FIG. 10.

FIG. 12 is a plan view illustrating a semiconductor device according to Modification Example 1 of Embodiment 1.

FIG. 13 is a plan view illustrating the semiconductor device according to Modification Example 1 of Embodiment 1.

FIG. 14 is a plan view illustrating the semiconductor device according to Modification Example 1 of Embodiment 1.

FIG. 15 is a cross-sectional view illustrating a semiconductor device according to Modification Example 2 of Embodiment 1.

FIG. 16 is a flowchart illustrating a manufacturing process of the semiconductor device according to Modification Example 2 of Embodiment 1.

FIG. 17 is a cross-sectional view during the manufacturing process of the semiconductor device according to Modification Example 2 of Embodiment 1.

FIG. 18 is a cross-sectional view during the manufacturing process of the semiconductor device subsequent to FIG. 17.

FIG. 19 is a cross-sectional view during the manufacturing process of the semiconductor device subsequent to FIG. 18.

FIG. 20 is a plan view illustrating a semiconductor device according to Embodiment 2.

FIG. 21 is a cross-sectional view taken along line B-B in FIG. 20.

FIG. 22 is a cross-sectional view taken along line C-C in FIG. 20.

FIG. 23 is a flowchart illustrating a manufacturing process of the semiconductor device according to Embodiment 2.

FIG. 24 is a cross-sectional view during the manufacturing process of the semiconductor device according to Embodiment 2.

FIG. 25 is a cross-sectional view during the manufacturing process of the semiconductor device subsequent to FIG. 24.

FIG. 26 is a cross-sectional view during the manufacturing process of the semiconductor device subsequent to FIG. 25.

FIG. 27 is a cross-sectional view during the manufacturing process of the semiconductor device subsequent to FIG. 26.

FIG. 28 is a cross-sectional view during the manufacturing process of the semiconductor device subsequent to FIG. 27.

FIG. 29 is a cross-sectional view illustrating a semiconductor device according to a modification example of Embodiment 2.

FIG. 30 is a cross-sectional view illustrating the semiconductor device according to the modification example of Embodiment 2.

FIG. 31 is a flowchart illustrating a manufacturing process of the semiconductor device according to the modification example of Embodiment 2.

FIG. 32 is a cross-sectional view during the manufacturing process of the semiconductor device according to the modification example of Embodiment 2.

FIG. 33 is a cross-sectional view illustrating a semiconductor device according to a comparative example.

FIG. 34 is a plan view illustrating a semiconductor module according to the comparative example.

### DESCRIPTION OF EMBODIMENTS

Hereinafter, embodiments of the present invention will be described in detail with reference to the drawings. Note that, in the drawings for describing the embodiments, members having the same functions are denoted by the same reference signs, and repeated description thereof will be omitted. In addition, in the following embodiments, the description of the same or similar parts will not be repeated in principle unless otherwise necessary.

### Embodiment 1

### <Structure of Semiconductor Device>

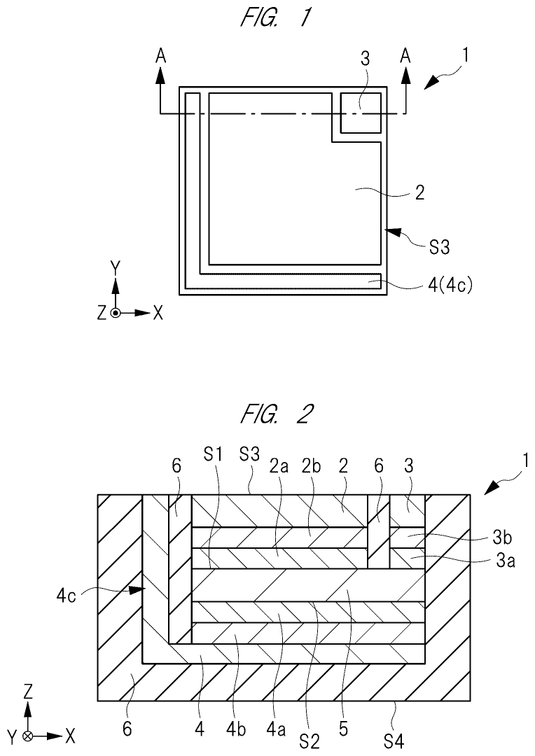

A structure of a semiconductor device according to the present embodiment will be described below with reference to FIGS. 1 to 3. As illustrated in FIG. 1, a semiconductor chip 1 which is a semiconductor device according to the present embodiment includes a terminal 2, a terminal 3, and a terminal 4 on a main surface S3 side. As illustrated in FIG. 2, the semiconductor chip 1 includes the main surface S3 and a main surface S4 opposite to the main surface S3. Both the main surface S3 and the main surface S4 are surfaces along an X-Direction and a Y-direction. the X-direction and the Y-direction are directions perpendicular to each other. A thickness direction (height direction) of the semiconductor chip 1 is a Z-direction perpendicular to both the X-direction and the Y-direction. The plan view in the present application means that an object is viewed along the Z-direction.

As illustrated in FIG. 2, the semiconductor chip 1 includes a semiconductor substrate 5 therein. The semiconductor substrate 5 is made of, for example, Si (silicon), SiC (silicon carbide), GaN (gallium nitride), Ga₂O₃ (gallium oxide), diamond, or the like. The shape of the semiconductor substrate 5 in plan view is rectangular. The semiconductor substrate 5 includes a main surface S1 and a main surface S2 opposite to the main surface S1. The main surface S1 is a surface of the semiconductor substrate 5 and is located on the main surface S3 side, and the main surface S2 is a surface of the semiconductor substrate 5 and is located on the main surface S4 side. That is, the main surface S3 is located on a bonding material (conductive connection layer) 2b side and a bonding material (conductive connection layer) 3b side with respect to the semiconductor substrate 5. The main surface S4 is located on a bonding material (conductive connection layer) 4b side with respect to the semiconductor substrate 5.

A source electrode 2a and a gate electrode 3a are connected to the main surface S1 of the semiconductor substrate 5. A drain electrode 4a is connected to the main surface S2 of the semiconductor substrate 5. The source electrode 2a, the gate electrode 3a, and the drain electrode 4a are spaced from each other and insulated from each other. The re-surfaces (surfaces on the main surface S3 side) of the source electrode 2a and the gate electrode 3a are made of, for example, Ni (nickel) or Cu (copper). In addition, the re-surface (surface on the main surface S4 side) of the drain electrode 4a is made of, for example, Ni (nickel), Cu (copper), or Au (gold).

Although not illustrated, the semiconductor substrate 5 is not formed only by a semiconductor, but has a stacked structure including wirings and an insulating layer on a main surface thereof, and includes a semiconductor element. As the semiconductor element formed on the semiconductor substrate 5, for example, a transistor such as a MOSFET (Metal Oxide Semiconductor Field Effect Transistor, MOS field effect transistor) or an IGBT (Insulated Gate Bipolar Transistor) can be considered. In addition, the semiconductor element formed on the semiconductor substrate 5 may be a rectifier element such as a diode.

Here, a case where a MOSFET is mounted on the semiconductor substrate 5 will be described as an example. Therefore, the semiconductor substrate 5 is a three-terminal element. In a case where the semiconductor element included in the semiconductor substrate 5 is a two-terminal element such as a diode, only one electrode and one terminal are connected to the surface of the semiconductor substrate 5 on the main surface S3 side. There may be three or more electrodes and three or more terminals connected to the surface of the semiconductor substrate 5 on the main surface S3 side. For example, it is conceivable that a source sense terminal, a temperature detection terminal, and the like are provided on the main surface S3 of the semiconductor substrate 5 in addition to the source terminal (terminal 2) and the gate terminal (terminal 3).

A terminal 2 is connected to a surface of the source electrode 2a on the main surface S3 side via the bonding material 2b. A terminal 3 is connected to a surface of the gate electrode 3a on the main surface S3 side via the bonding material 3b. A terminal 4 is connected to a surface of the drain electrode 4a on the main surface S4 side via the bonding material 4b. That is, the terminal 2 is electrically connected to the semiconductor substrate 5 via the bonding material 2b and the source electrode 2a. The terminal 3 is electrically connected to the semiconductor substrate 5 via the bonding material 3b and the gate electrode 3a. The terminal 4 is electrically connected to the semiconductor substrate 5 via the bonding material 4b and the drain electrode 4a. Each of the terminals 2, 3, and 4 is made of, for example, Cu (copper), W (tungsten), Al (aluminum), Mo (molybdenum), or the like., Each of the bonding materials (bonding layers) 2b, 3b, and 4b is a bonding portion having conductivity, and is made of, for example, solder, a sintered material, or a bump.

The terminal 4 includes an extraction electrode 4c that extends outward in the Y-direction and the X-direction with respect to a stacked body including the semiconductor substrate 5, the source electrode 2a, the gate electrode 3a, the drain electrode 4a, the bonding materials 2b, 3b, and 4b, and the terminals 2 and 3 stacked in the Z-direction, and extends toward the main surface S3 at a position spaced from the stacked body. The extraction electrode 4c which is a part of the terminal 4 extends in the Z-direction and is exposed on the main surface S3. The shape of the stacked body in plan view is rectangular. As illustrated in FIG. 1, the extraction electrode 4c (terminal 4) has an L-shaped planar layout in which a portion of the stacked body extending along one side extending in the Y-direction is connected to a portion of the stacked body extending along one side extending in the X-direction.

As illustrated in FIG. 2, the terminal 4 includes a plate-like portion that is in contact with the bonding material 4b and extends along an X-Y plane, an extraction electrode 4c that extends along an X-Z plane, and an extraction electrode 4c that extends along a Y-Z plane. Therefore, the terminal 4 has an L-shaped cross-sectional shape. The plate-like portion extending along the X-Y plane and the extraction electrode 4c may be integrated, or may be bonded to each other with a bonding material interposed therebetween. In a case where the plate-like portion and the extraction electrode 4c are integrated, the manufacturing method of the terminal 4 (conductor 20 to be described later) is simple, but material processing is required. Thus, the manufacturing cost increases as compared with the case of bonding the plate-like portion and the extraction electrode 4c.

An insulating material (sealing material) 6 is buried between the stacked body and the extraction electrode 4c. In addition, the insulating material 6 is buried between a stacked body including the source electrode 2a, the bonding material 2b, and the terminal 2 and a stacked body including the gate electrode 3a, the bonding material 3b, and the terminal 3. In addition, the insulating material 6 continuously covers and seals the side surfaces in the X-direction and the Y-direction of a structure including the terminal 4, the semiconductor substrate 5, the source electrode 2a, the gate electrode 3a, the drain electrode 4a, the bonding materials 2b, 3b, and 4b, and the terminals 2, 3, and 4, and the surface of the terminal 4 on the main surface S4 side. The insulating material 6 is made of, for example, mold resin.

The terminal 4 is extracted toward the main surface S3 from a position where the terminal 4 is bonded to the bonding material 4b by the plate-like portion extending along the X-Y plane and the extraction electrode 4c. The terminal is not exposed on the surface other than the main surface S3 of the surface of the semiconductor chip 1. In other words, the surface other than the main surface S3 among the surfaces of the semiconductor chip 1 is entirely covered with the insulating material 6.

The shape of the semiconductor chip 1 in plan view and the shape of each side surface are rectangular. That is, the shape of the semiconductor chip 1 is a rectangular parallelepiped. The side surfaces of the semiconductor chip 1 in the X-direction and the Y-direction and the main surface S4 are formed of the insulating material 6, and the surface of the terminal 4 on the main surface S4 side is not exposed. The surfaces of the insulating material 6 and the terminals 2, 3, and 4 are exposed on the main surface S3. That is, the main surface S3 is constituted by the surfaces of the insulating material 6 and the terminals 2, 3, and 4. The main surface S3 is flat. On the main surface 3, the periphery of each of the terminals 2, 3, and 4 is entirely surrounded by the insulating material 6.

The shape of the terminal (gate terminal) 3 in plan view is rectangular. In plan view, the area of the terminal (gate terminal) 3 is smaller than that of the terminal (source terminal) 2. The shortest distance between 2, 3, and 4 is preferably equal to or less than the length of one side (short side) of the terminal 3 in plan view. This is because an increase in the size of the semiconductor device becomes a problem when the shortest distance is large.

The semiconductor substrate 5 is obtained by dividing a semiconductor wafer by cutting. The semiconductor substrate 5 including the semiconductor element, the source electrode 2a, the gate electrode 3a, and the drain electrode 4a may be referred to as a semiconductor chip. However, here, a substrate including the semiconductor element is referred to as a semiconductor substrate 5, and an object obtained by electrically connecting and sealing the terminals 2, 3, and 4 to the semiconductor substrate 5 is referred to as a semiconductor chip 1.

### <Structure of Semiconductor Module>

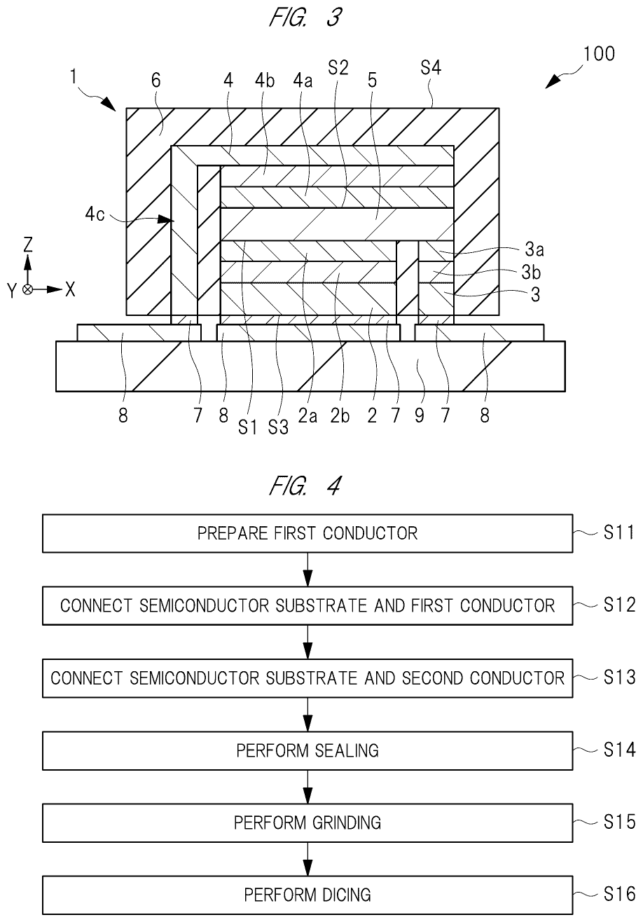

FIG. 3 illustrates a cross-sectional view of a semiconductor module 100 on which the semiconductor device (semiconductor chip 1) of the present embodiment is mounted. The semiconductor chip 1 illustrated in FIG. 3 is obtained by turning the semiconductor chip 1 illustrated in FIG. 2 upside down, and the position of the cross section illustrated in FIG. 3 is the same as the position of the cross section illustrated in FIG. 2.

As illustrated in FIG. 3, each of the terminals 2, 3, and 4 on the main surface S3 of the semiconductor chip 1 is connected to a separate wiring 8 via a bonding material 7. The wiring 8 is a wiring pattern made of a conductor provided on the main surface of an insulating substrate 9. The bonding material 7 is made of, for example, solder, a sintered material, or a bump. The insulating substrate 9 is made of, for example, AIN (aluminum nitride). Although not illustrated, the semiconductor module illustrated in FIG. 3 may be disposed, for example, in a resin case, and a structure including the semiconductor chip 1 on the main surface of the insulating substrate 9 may be sealed with a resin poured into the resin case.

Here, all the terminals of the semiconductor chip 1 are surface-mounted on the insulating substrate 9 side by using only the bonding material 7 on the main surface S3 side. That is, since the terminal of the semiconductor chip 1 is not exposed on the main surface S4 side of the semiconductor chip 1, the semiconductor chip 1 and the wiring 8 are not connected using a bonding wire, a conductive ribbon, or the like.

### <Manufacturing Method for Semiconductor Device>

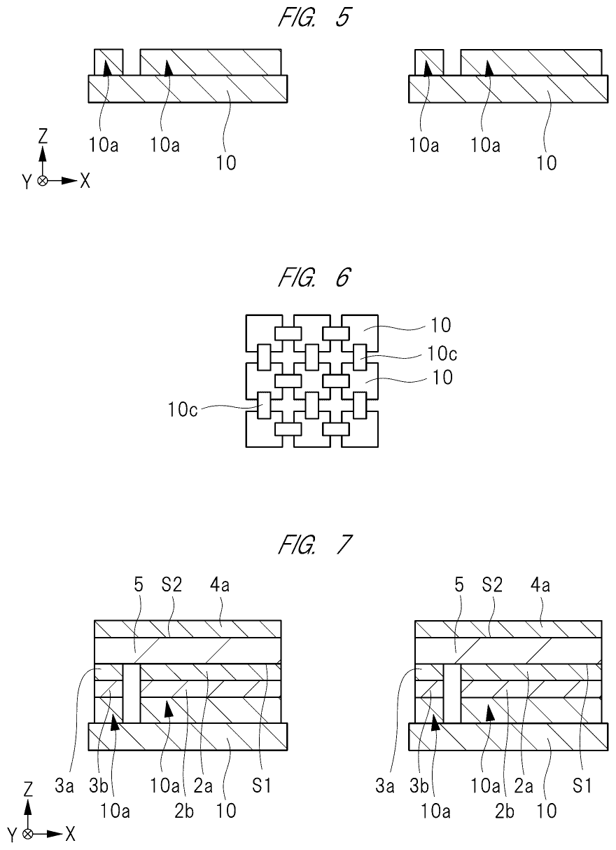

Next, a manufacturing method for the semiconductor device of the present embodiment will be described with reference to FIGS. 5 to 11 while referring to the flowchart of FIG. 4.

First, as illustrated in FIG. 5, a plurality of conductors 10 are prepared (Step S11 in FIG. 4). The conductors 10 are made of, for example, Cu (copper), W (tungsten), Al (aluminum), Mo (molybdenum), or the like. The conductor 10 includes a plate-shaped support portion and two protrusions 10a that are arranged on a surface of the support portion to be spaced from each other. The two protrusions 10a are parts to be the terminals 2 and 3 later. As illustrated in FIG. 6, the plurality of conductors 10 may be connected to each other via the connection portion 10c to be integrated. The conductor 10 illustrated in FIG. 5 is already divided. The divided conductor 10 has an advantage of low member cost, but it takes time and effort to align the divided conductor with a semiconductor substrate to be connected in a later process. The integrated conductor 10 of FIG. 6 has an advantage that the alignment is easy, but the member cost is high.

Then, as illustrated in FIG. 7, each of the plurality of conductors 10 and each of the plurality of semiconductor substrates 5 are connected (Step S12 in FIG. 4). Specifically, a plurality of semiconductor substrates 5 that has a main surface S1 and a main surface S2 opposite to the main surface S1, in which a source electrode 2a and a gate electrode 3a are provided on the main surface S1, and a drain electrode 4a is provided on the main surface S2 are prepared. Subsequently, the source electrode 2a is connected to one of the two protrusions 10a of each conductor 10 via a bonding material 2b, and the gate electrode 3a is connected to the other of the two protrusions 10a via a bonding material 3b.

Then, as illustrated in FIG. 8, each of the plurality of conductors 20 is connected to each of the plurality of semiconductor substrates 5 (Step S13 in FIG. 4). That is, a plurality of conductors 20 configured to connect a plate-like portion extending along the X-Y plane, an extraction electrode (protrusion) 4c extending along the X-Z plane, and an extraction electrode (protrusion) 4c extending along the Y-Z plane to each other are prepared. The extraction electrode 4c is connected to the surface of the plate-like portion as a support portion, and is formed on the surface. Note that the plurality of semiconductor substrates 5 may be prepared at the time of Step S11, and the plurality of conductors 20 may be prepared at the time of Step S11 or S12. Steps 12 and 13 may be executed simultaneously. That is, the conductors 10 and 20 may be simultaneously connected to the semiconductor substrate 5. In addition, Step S13 may be executed before Step S12.

Here, first, the conductor 10 and the semiconductor substrate 5 connected to each other are turned upside down. Subsequently, the drain electrode 4a on the main surface S4 side of the semiconductor substrate 5 is connected to the surface of the plate-like portion extending along the X-Y plane in each conductor 20 on the side where the extraction electrode 4c protrudes, via the bonding material 4b. Here, in a state where the extraction electrode 4c is spaced in the Y-direction and the X-direction from a stacked body including the semiconductor substrate 5, the source electrode 2a, the gate electrode 3a, the drain electrode 4a, the bonding materials 2b, 3b, and 4b, and the terminals 2 and 3, the stacked body is connected to the surface of the plate-like portion. Each of the bonding materials 2b, 3b, and 4b is made of, for example, solder, a sintered material, or a bump.

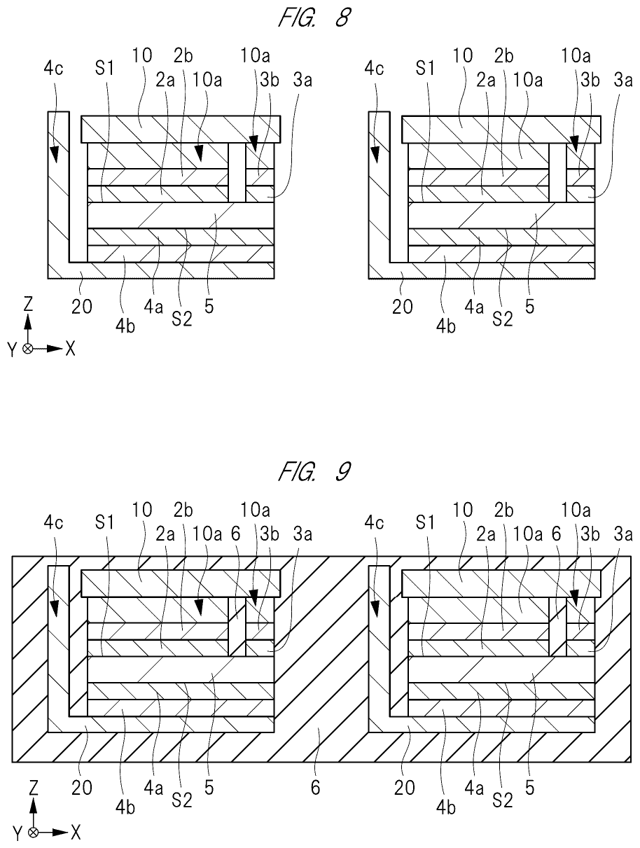

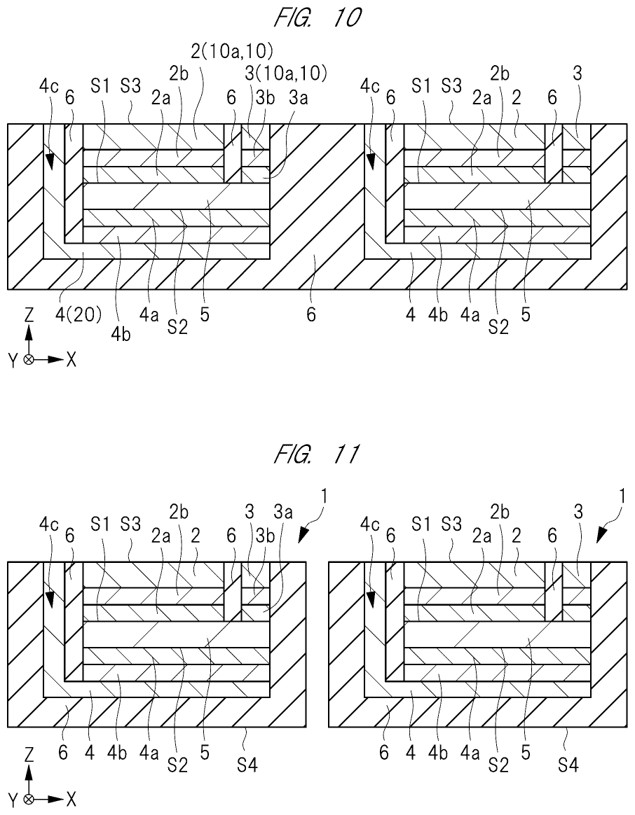

Then, as illustrated in FIG. 9, each of the plurality of semiconductor substrates 5 and the plurality of conductors 10 and 20 is sealed with the insulating material 6 (Step S14 in FIG. 4). The insulating material 6 is made of, for example, mold resin. In FIG. 9, the entirety of the surfaces of the conductors 10 and 20 is sealed, but a part of the surfaces of the conductors 10 and 20 (the upper end of each conductor in FIG. 9) may be exposed above the bonding materials 2b and 3b. Further, in the Z-direction, the height positions of the upper surface of the conductor 10 (the surface opposite to the semiconductor substrate 5 side) and the uppermost surface of the conductor 20 may not coincide with each other and may be shifted from each other. This is because the upper surfaces are flattened by grinding performed in Step S15 which will be described later.

Then, as illustrated in FIG. 10, the conductor 10 and the conductor 20 are ground from the top to flatten the surfaces of the insulating material 6, the conductor 10, and the conductor 20 (Step S15 in FIG. 4). Here, grinding is performed until the support portion constituting the conductor 10 is removed, and the two protrusions 10a are separated from each other. As a result, the remaining two protrusions 10a of the conductor 10 constitute the terminals 2 and 3, respectively. In addition, the partially ground conductor 20 constitutes the terminal 4. The surfaces of the insulating material 6 and the terminals 2, 3, and 4 flattened in the grinding step constitute the main surface S3.

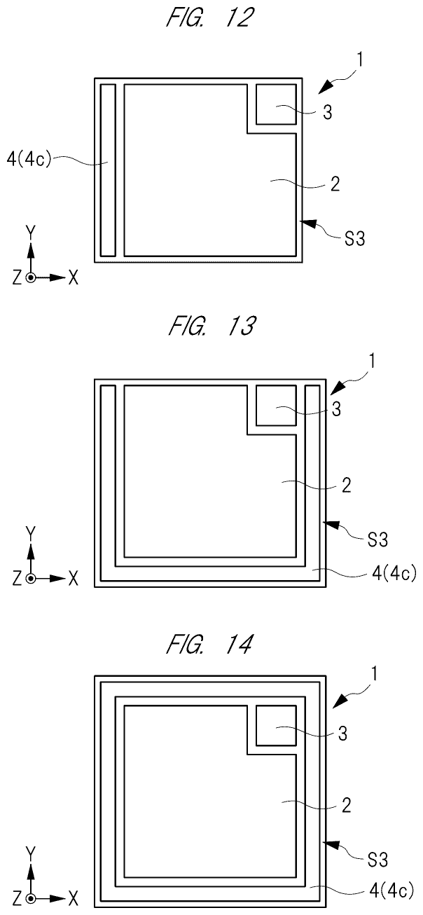

Then, as illustrated in FIG. 11, dicing is performed to cut the insulating material 6 between the adjacent terminals 4, whereby a plurality of divided semiconductor chips 1 can be obtained (Step S16 in FIG. 4). The bottom surface of the insulating material 6, that is, the surface opposite to the main surface S3 forms the main surface S4. In this manner, the semiconductor device of the present embodiment is substantially completed.

In the case of manufacturing the semiconductor module illustrated in FIG. 3, after the semiconductor chip 1 and the insulating substrate 9 provided with the pattern of the wiring 8 on the main surface are prepared, the terminals 2, 3, and 4 exposed on the main surface S3 of the semiconductor chip 1 are connected to the wiring 8 via the bonding material 7.

### Effects of Present Embodiment

In the manufacturing process of the semiconductor device, a conduction inspection is performed on the semiconductor chip. Since the inspection is performed by applying a voltage to each terminal of the semiconductor chip, it is necessary to prevent aerial discharge between the terminals at the time of inspection for off-characteristic evaluation. For example, in inspection of an element to which a higher voltage than that of a Si semiconductor element is applied, such as a Sic power semiconductor element, a high electric field is applied, and thus, it is necessary to take measures particularly for preventing discharge. In order to prevent discharge, as an inspection method, means for performing measurement in a state where the semiconductor device is immersed in an insulating liquid or pressurized is considered, but it is difficult to perform measurement in a chip state.

In addition, it is difficult to cause a large current to flow by bringing a probe into contact with a miniaturized semiconductor chip in an inspection for on-characteristic evaluation. Since the SiC semiconductor element has a chip size smaller than that of the Si semiconductor element, it is particularly difficult to perform probe inspection on the semiconductor chip.

Due to these restrictions, it is not possible to perform sufficient inspection on a semiconductor chip alone, and it is conceivable that an inspection is performed after modularization in which a plurality of semiconductor chips are connected in parallel (see FIG. 34), sealed with an insulating material, and connection of a main current path is made by a bus bar. As a result, the plurality of other semiconductor chips connected in parallel are also treated as defects due to the defect of one semiconductor chip, and the yield in manufacturing of the module decreases, so that the manufacturing cost of the semiconductor device increases.

In addition, when the semiconductor module is formed by connecting the semiconductor chips in parallel, it is conceivable to use a bonding wire 41 as illustrated in FIGS. 33 and 34 as a comparative example. In FIG. 33, illustration of the insulating material (sealing material) is omitted, and in FIG. 34, illustration of the insulating material and some of the bonding wires 41 is omitted.

As illustrated in FIG. 33, unlike the semiconductor chip 1 illustrated in FIG. 1, a semiconductor chip 1x that is a semiconductor device of a comparative example is electrically connected to the drain electrode 4a of the semiconductor substrate 5, and an electrode (terminal) that extracts the drain to the source electrode 2a and the gate electrode 3a side is not formed. Further, an electrode that is electrically connected to each of the source electrode 2a and the gate electrode 3a of the semiconductor substrate 5, and extracts the source and the gate toward the drain electrode 4a is not formed.

The drain electrode 4a is connected to the wiring 8 immediately below the semiconductor substrate 5 via the bonding material 7, and each of the source electrode 2a and the gate electrode 3a is connected to the wiring 8 via the bonding wire 41 in contact with the upper surfaces thereof.

In order to form such a semiconductor module 100a of the comparative example, a wire bonding process is required in addition to the surface mounting process of connecting the drain electrode 4a to the wiring 8, and thus the manufacturing cost of the semiconductor device increases. In addition, when the bonding wire 41 is formed at a high position as illustrated in FIG. 33, it is necessary to increase a thickness of a resin layer for sealing the semiconductor chip 1x and the bonding wire 41, and an increase in size of the semiconductor device becomes a problem.

In addition, even if a large current is intended to flow in the inspection on the semiconductor module 100a on which wire bonding has been performed, it is difficult to cause a large current to flow because the bonding wire 41 (or ribbon) has a small cross-sectional area. In addition, in the completed semiconductor module, there is a problem that wiring resistance increases by using the bonding wire 41 having a small cross-sectional area.

In addition, in the semiconductor chip 1x of the comparative example, heat is likely to rise on the surface side to which the bonding wire 41 is connected. Therefore, it is conceivable to provide a mechanism for cooling both the front surface side where the bonding wire 41 is connected only to the gate and the back surface side to which the terminal 4 is connected. However, providing the cooling mechanisms on both sides leads to an increase in size of the semiconductor device (semiconductor module) and an increase in manufacturing cost.

In order to solve these problems, it is conceivable to extract a terminal on the main surface side to the main surface side of the semiconductor chip. As a method therefor, it is conceivable to provide a through electrode that penetrates the semiconductor substrate and is electrically connected to the back electrode (drain electrode). However, in the process of forming the semiconductor substrate having such a structure, adhesion of dust due to formation of the through-hole, processing variation of the through-hole, defective filling (insufficient filling) of the through-electrode, and the like are likely to occur, and there is a concern that the yield in manufacturing of the semiconductor device is reduced.

Therefore, in the present embodiment, instead of providing the through electrode on the semiconductor substrate 5, the extraction electrode 4c that extracts the terminal 4 on the main surface S4 side of the semiconductor chip 1 to the main surface S3 side is provided at a position spaced from the semiconductor substrate 5. As a result, all the terminals 2, 3, and 4 for electrically connecting the semiconductor chip 1 and the outside are collected on the main surface S3 of the semiconductor chip 1.

As a result, in the inspection process of the semiconductor device, it is possible to inspect a single chip without connecting a plurality of semiconductor chips 1 in parallel. This is because the semiconductor chip 1 is sealed with the insulating material 6, and the inspection in a state where the main surface S4 is adhered or attracted becomes easy. Since there is no terminal on the main surface S4, fixing the main surface S4 makes it easy to perform an inspection by immersing the semiconductor chip 1 in an insulating liquid or pressurizing the semiconductor chip 1. Therefore, it is possible to prevent discharge and to inspect the semiconductor chip 1 alone at a high voltage. Therefore, it is not necessary to perform an inspection by connecting a plurality of semiconductor chips in parallel, and it is possible to prevent an occurrence of a situation in which other semiconductor chips are treated as defects due to a defect of one semiconductor chip. Thus, it is possible to improve the yield of the semiconductor device, and to prevent an increase in the manufacturing cost of the semiconductor device.

In addition, since the terminal is not exposed on the main surface S4 on the opposite side of the surface-mounted main surface S3, the wire bonding process is unnecessary. Therefore, since the semiconductor device can be mounted only by the surface mounting process using the bonding material 7, it is possible to reduce the manufacturing cost of the semiconductor device. In addition, since the bonding wire is unnecessary, it is possible to reduce the size of the semiconductor device. As a result, since the resin layer for sealing the semiconductor chip 1 can be made thinner than that in the comparative example, it is possible to reduce the size of the semiconductor device.

In addition, even in a case where the conduction inspection is performed after the semiconductor chip 1 is mounted on the insulating substrate 9, the bonding wire is unnecessary, so that the inspection using a large current through only the bonding material 7 is facilitated. Further, in the completed semiconductor module 100, since a bonding wire having a small cross-sectional area is unnecessary, it is possible to reduce the wiring resistance. In addition, since there is no bonding wire, it is possible to prevent an occurrence of a problem that heat easily rises on the main surface side of the semiconductor chip on the side to which the bonding wire is connected, as in the comparative example. Thus, it is not necessary to provide a mechanism for cooling both the main surface S3 and the main surface S4, and it is sufficient that only one surface on the mounted main surface S3 side is cooled. As a result, it is possible to reduce the semiconductor device (semiconductor module) and to reduce the manufacturing cost.

In the present embodiment, since the through hole and the through electrode penetrating the semiconductor substrate 5 are not formed, it is possible to prevent the occurrence of dust adhesion due to the formation of the through-hole and the through electrode, processing variation of the through hole, defective filling of the through electrode, and the like. As a result, it is possible to improve the yield in manufacturing the semiconductor device.

### Modification Example 1

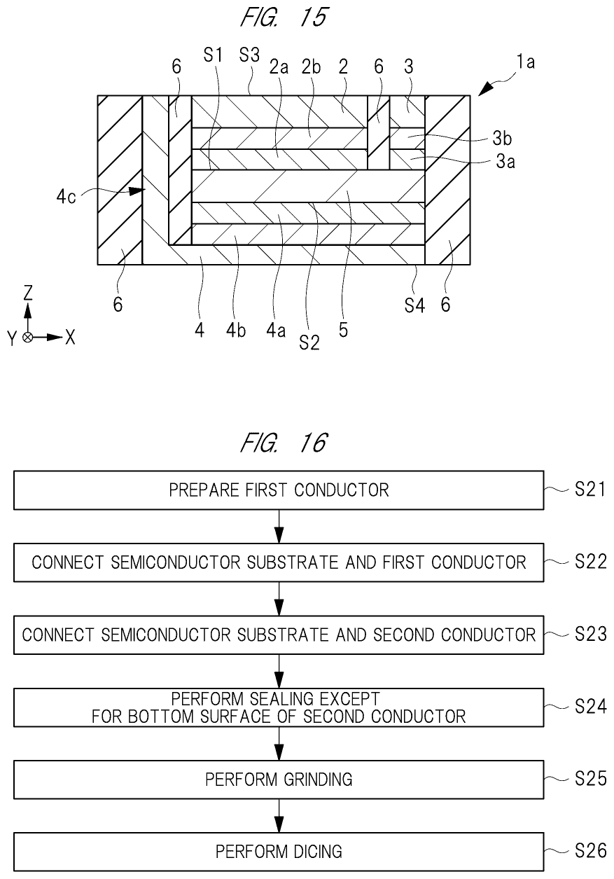

The planar layout of the terminal 4 (extraction electrode 4c) on the main surface S3 of the semiconductor chip 1 is not limited to the L-shape, and may have a shape as illustrated in FIGS. 12 to 13. In the planar layout illustrated in FIG. 12, the terminal 4 has an I-shape that extends along only one side of the terminal 2 having a substantially rectangular planar shape. In the planar layout illustrated in FIG. 13, the terminal 4 has a U-shape continuously extending along three sides of the terminal 2. In the planar layout illustrated in FIG. 14, the terminal 4 has a continuous rectangular annular structure along the four sides of the terminal 2.

### Modification Example 2

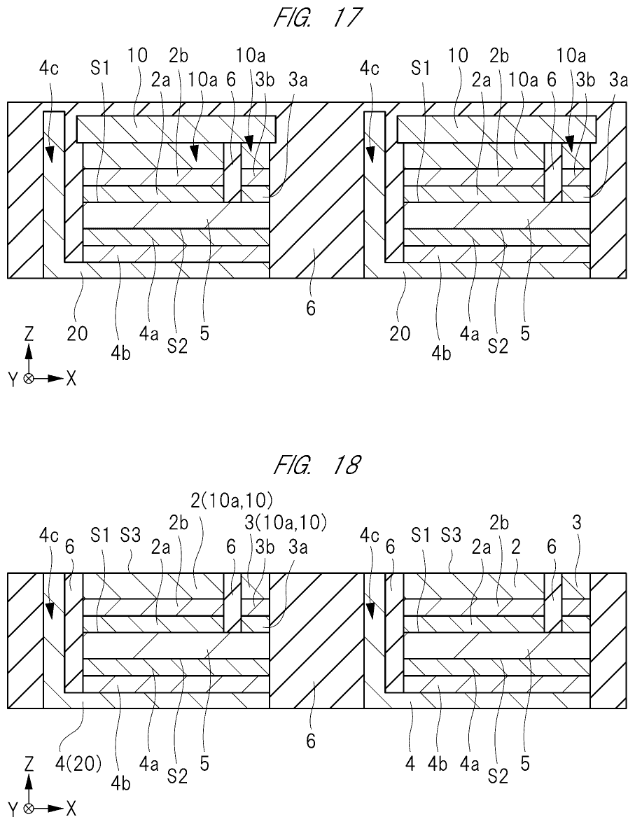

As illustrated in FIG. 15, in the main surface S4 of the semiconductor chip la, the surface of the terminal 4 may be exposed from the insulating material 6. Here, in the portion constituting the terminal 4, a part of the plate-like portion extending along the X-Y plane in contact with the bonding material 4b is exposed. That is, among the surfaces of the plate-like portion, the surface opposite to the semiconductor substrate 5 is exposed from the insulating material 6.

Next, a manufacturing method for a semiconductor device according to the present modification example will be described with reference to FIGS. 17 to 19 while referring to the flowchart of FIG. 16.

First, processes similar to Steps S11 to S13 in FIG. 4 are executed (Steps S21 to S23 in FIG. 16).

Then, as illustrated in FIG. 17, each of the plurality of semiconductor substrates 5 and the plurality of conductors 10 and 20 is sealed with the insulating material 6 (Step S24 in FIG. 16). Here, sealing is performed in a state (protected state) in which a surface (bottom surface) on the side opposite to the semiconductor substrate 5 side among the surfaces of the plurality of conductors 20 is covered by adhering to a tape (not illustrated).

However, the sealing is not prevented using the tape, and after the conductor 20 is sealed as in Step S14 of FIG. 4, grinding is performed to expose the surface (bottom surface) on the opposite side to the semiconductor substrate 5 side among the surfaces of the conductor 20, whereby the structure illustrated in FIG. 17 may be obtained.

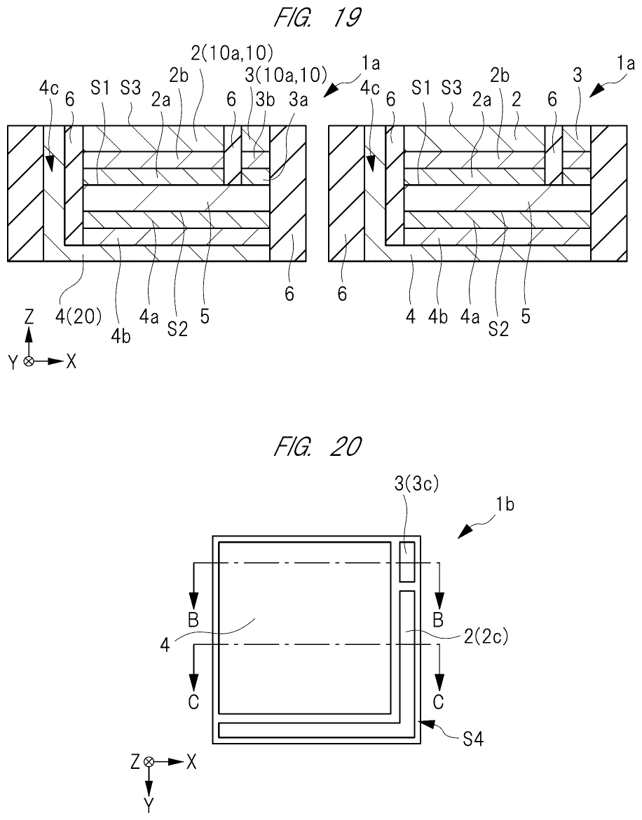

Then, as illustrated in FIG. 18, the terminals 2, 3, and 4 are formed by executing a grinding process similar to Step S15 in FIG. 4 (Step S25 in FIG. 16).

Then, as illustrated in FIG. 19, a dicing process similar to Step S16 in FIG. 4 is executed to obtain a plurality of divided semiconductor chips la (Step S26 in FIG. 16). In this manner, the semiconductor device of the present modification example is substantially completed.

In the present modification example, it is possible to obtain effects similar to those of the semiconductor device described with reference to FIGS. 1 to 3. In addition, since there is no insulating material 6 covering the terminal 4 on the main surface S4, it is possible to reduce the size of the semiconductor device, the cooling effect on the main surface S4 side is enhanced. Further, it is also possible to perform inspection and measurement by bringing the probe into contact with both the main surface S3 side and the main surface S4 side. The exposed area of the terminal 4 on the main surface S4 side is larger than the exposed area of the terminal 4 on the main surface S3 side. Thus, the probe inspection on the terminal 4 becomes easier.

### Embodiment 2

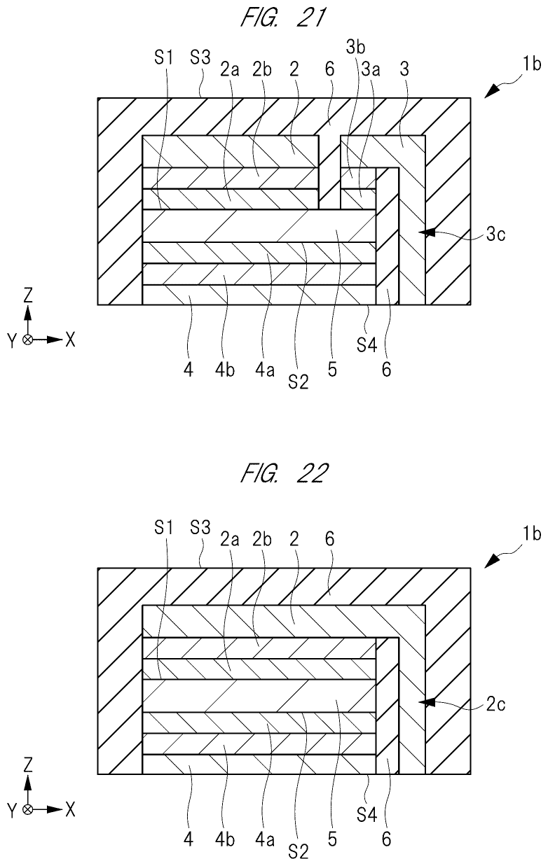

In Embodiment 1, a case where the terminal 4 connected to the drain electrode 4a is extracted to the side where the other terminals 2 and 3 are formed has been described. In the following, conversely, a case where the terminal 2 or 3 is extracted to the main surface S4 side where the terminal 4 is formed will be described with reference to FIGS. 20 to 28.

Unlike FIG. 1, FIG. 20 illustrates the main surface S4 of a semiconductor chip 1b. The terminal 4 connected to the drain electrode 4a of the semiconductor substrate 5 via the bonding material 4b is exposed on the main surface S4 of the semiconductor chip 1b. In addition, the terminal 2 (extraction electrode 2c) connected to the source electrode 2a of the semiconductor substrate 5 via the bonding material 2b is exposed on the main surface S4. Further, the terminal 3 (extraction electrode 3c) connected to the gate electrode 3a of the semiconductor substrate 5 via the bonding material 3b is exposed on the main surface S4. The terminal 2 on the main surface S4 has an L-shaped layout. However, the shape of each of the terminal 2 and the terminal 3 on the main surface S4 may be any of the L-shape, the I-shape, and the U-shape described with reference to FIGS. 1, 12, and 13.

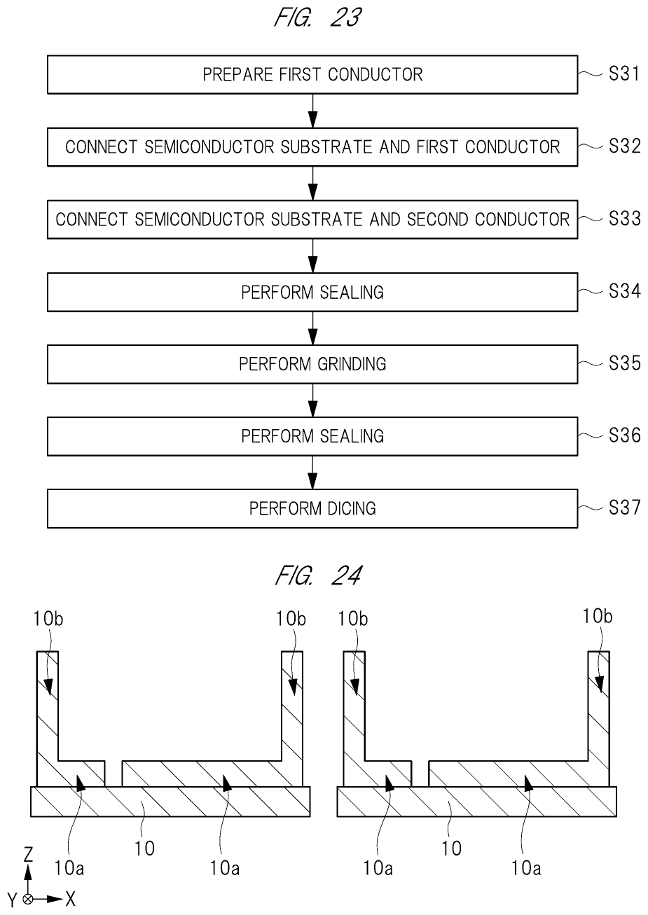

FIG. 21 illustrates a cross-sectional view taken along line B-B in FIG. 20, and FIG. 22 illustrates a cross-sectional view taken along line C-C in FIG. 20. As illustrated in FIG. 21, the terminal 3 includes a plate-like portion that is in contact with a bonding material 3b and extends along the X-Y plane, and an extraction electrode 3c that extends along the X-Z plane. As illustrated in FIGS. 21 and 22, the terminal 2 includes a plate-like portion that is in contact with a bonding material 2b and extends along the X-Y plane, an extraction electrode 2c that extends along the X-Z plane, and an extraction electrode 2c that extends along the Y-Z plane. Each of the extraction electrodes 2c and 3c extends in the Z-direction, and one end portion in the extending direction terminates at the main surface S4. The terminals 2 and 3 arranged in the X-direction and the Y-direction are spaced from each other.

The terminal is not exposed on the surface other than the main surface S4 of the surface of the semiconductor chip 1b. In other words, the surface other than the main surface S4 among the surfaces of the semiconductor chip 1b is entirely covered with the insulating material 6.

Next, a manufacturing method for the semiconductor device of the present embodiment will be described with reference to FIGS. 24 to 28 while referring to the flowchart of FIG. 23.

First, as illustrated in FIG. 24, a plurality of conductors 10 are prepared (Step S31 in FIG. 23). The conductor 10 includes a support portion and two protrusions 10a that are arranged on a surface of the support portion to be spaced from each other. The two protrusions 10a are parts to be the terminals 2 and 3 later. Each of the two protrusions 10a further includes a protrusion 10b protruding on the upper surface thereof. In other words, the protrusion 10a is formed on the surface of the support portion via the protrusion 10b. The two protrusions 10b are portions to be the extraction electrodes 2c and 3c, which are parts of the terminals 2 and 3, respectively, later. The conductor 10 includes the support portion and the protrusions 10a and 10b.

Then, as illustrated in FIG. 25, each of the plurality of conductors 10 and each of the plurality of semiconductor substrates 5 are connected (Step S32 in FIG. 23). Specifically, a plurality of semiconductor substrates 5 that has a main surface S1 and a main surface S2 opposite to the main surface S1, in which a source electrode 2a and a gate electrode 3a are provided on the main surface S1, and a drain electrode 4a is provided on the main surface S2 are prepared. Subsequently, the source electrode 2a is connected to one of the two protrusions 10a of each conductor 10 via a bonding material 2b, and the gate electrode 3a is connected to the other of the two protrusions 10a via a bonding material 3b. The semiconductor substrate 5 is connected to the protrusion 10a at a position spaced from the protrusion 10b. That is, a stacked body including the semiconductor substrate 5 and the drain electrode 4a is spaced from the protrusion 10b, and the source electrode 2a and the gate electrode 3a are connected to the surfaces of the plurality of protrusions 10a, which are the surfaces of the conductor 10, via the bonding materials 2b and 3b, respectively.

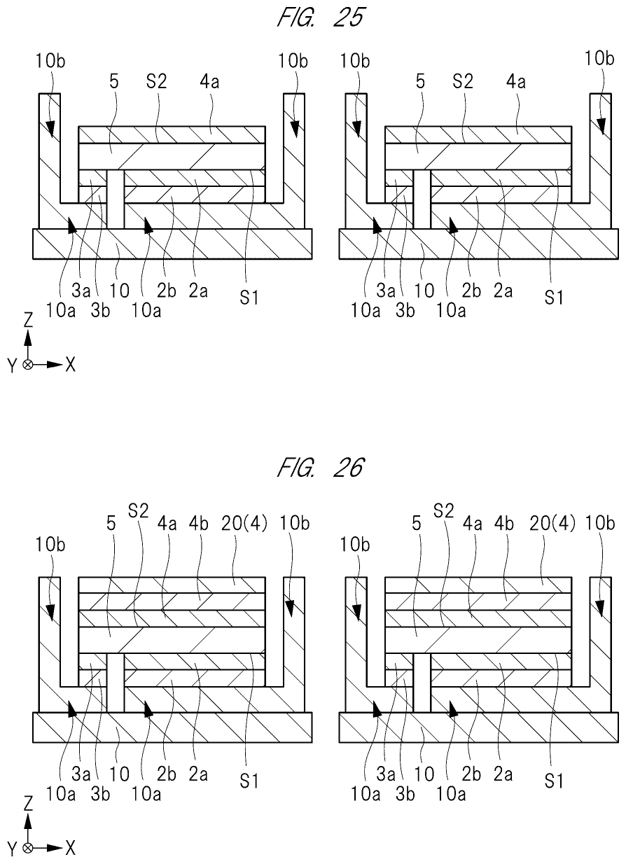

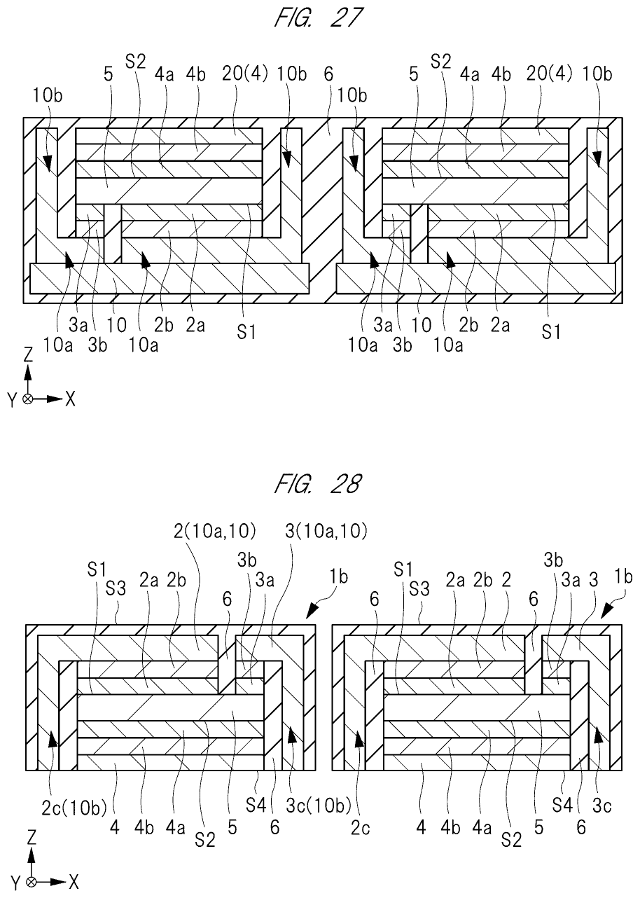

Then, as illustrated in FIG. 26, each of the plurality of conductors 20 is connected to each of the plurality of semiconductor substrates 5 (Step S33 in FIG. 23). The conductor 20 includes only a plate-like portion extending along the X-Y plane, and constitutes the terminal 4. Here, the drain electrode 4a on the main surface S2 side of the semiconductor substrate 5 is connected to the surface of each conductor 20 via the bonding material 4b. The conductor 20 is connected to the semiconductor substrate 5 at the position spaced from the protrusion 10b. Steps 32 and 33 may be executed simultaneously. That is, the conductors 10 and 20 may be simultaneously connected to the semiconductor substrate 5. In addition, Step S33 may be executed before Step S32.

Then, as illustrated in FIG. 27, each of the plurality of semiconductor substrates 5 and the plurality of conductors 10 and 20 is sealed with the insulating material 6 (Step S34 in FIG. 23). In FIG. 27, parts of the surfaces of the conductors 10 and 20 are exposed, but all of the surfaces of the conductors 10 and 20 may be sealed. Further, in the Z-direction, the height positions of the upper surface of the conductor 20 (the surface opposite to the semiconductor substrate 5) and the uppermost surface of the conductor 10 (protrusion 10b) may not coincide with each other and may be shifted from each other. This is because the upper surfaces are flattened by grinding performed in Step S35 which will be described later.

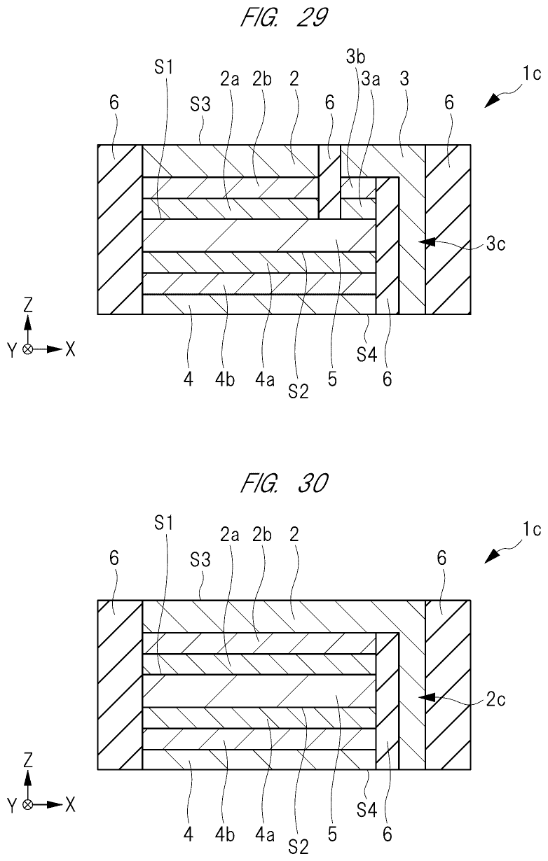

Then, as illustrated in FIG. 28, the conductor 10 and the conductor 20 are ground from both sides in the Z-direction (Step S35 in FIG. 23).

Here, first, a structure including the semiconductor substrate 5, the conductors 10 and 20, and the insulating material 6 is turned upside down. Subsequently, the conductor 10 is ground from the top. That is, the conductor 10 and the insulating material 6 are ground until the support portion constituting the conductor 10 is removed and the two protrusions 10a are separated from each other. As a result, the remaining one set of protrusions 10a and 10b constitutes the terminal 2, and the other one set of protrusions 10a and 10b constitutes the terminal 3.

Subsequently, the sealing process is performed again (Step S36 in FIG. 23). Here, the terminals 2 and 3 (protrusions 10a) exposed by the grinding are covered with the insulating material 6. Note that the insulating material 6 and the insulating material 6 formed in Step S34 are formed in separate processes, but are denoted by the same reference signs here, and are illustrated integrally with each other in FIG. 28.

Subsequently, dicing is performed to cut the insulating material 6 between the adjacent semiconductor substrates 5, whereby a plurality of divided semiconductor chips 1b can be obtained (Step S37 in FIG. 23). In the semiconductor chip 1b, a flat surface including the surfaces of the insulating material 6 and the terminals 2, 3, and 4 exposed on the lower side (the bonding material 4b side with respect to the semiconductor substrate 5) in FIG. 28 constitutes the main surface S4. The upper surface of the insulating material 6, which is the surface on the opposite side of the main surface S4 of the semiconductor chip 1b (the surface on the bonding material 2b side with respect to the semiconductor substrate 5) and is formed in the above-described re-sealing step, constitutes the main surface S3. In this manner, the semiconductor device of the present embodiment is substantially completed.

In the semiconductor device and the manufacturing method for the same according to the present embodiment, it is possible to obtain the same effects similar to those of Embodiment 1. Furthermore, the semiconductor chip 1b of the present embodiment has higher heat dissipation than the semiconductor chip 1 of Embodiment 1. This is because the surface on which the drain electrode 4a is formed has a larger area occupied by the conductor (terminal) in the area of the semiconductor chip 1b in plan view than the surface on which the source electrode 2a and the gate electrode 3a are formed. That is, in the present embodiment, since heat can be dissipated from substantially entire main surface S4, thermal resistance is low.

### Modification Examples

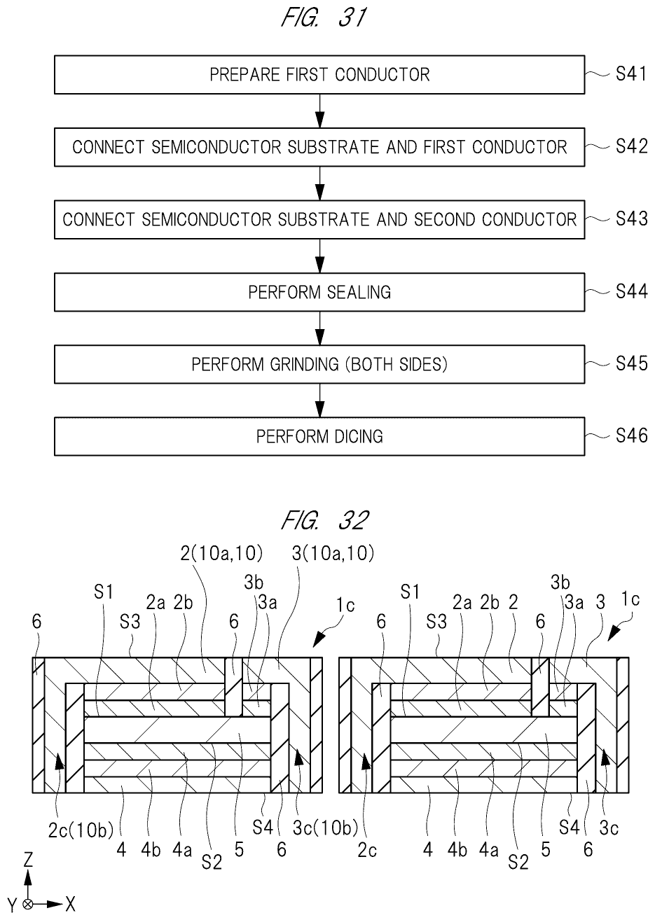

As illustrated in FIGS. 29 and 30, on the main surface S3 of a semiconductor chip 1c, the surfaces of the terminals 2 and 3 may be exposed from the insulating material 6. Here, among the surfaces of the terminals 2 and 3, the surface opposite to the main surface S1 of the semiconductor substrate 5 is exposed from the insulating material 6. These are cross sections illustrated in FIGS. 29 and 30, and are cross sections at places corresponding to the cross sections illustrated in FIGS. 21 and 22.

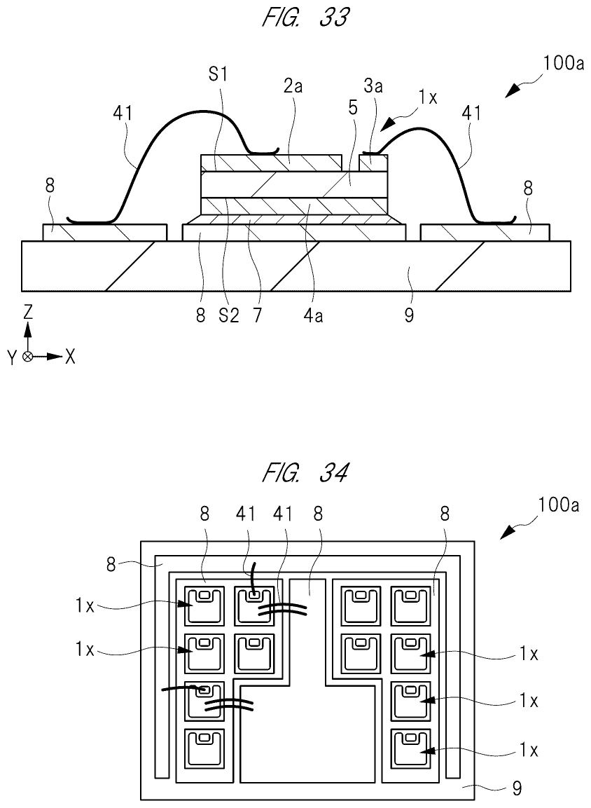

Next, a manufacturing method for a semiconductor device according to the present modification example will be described with reference to FIG. 32 while referring to the flowchart of FIG. 31.

First, processes similar to Steps S31 to S34 in FIG. 23 are executed (Steps S41 to S44 in FIG. 31).

Then, as illustrated in FIG. 32, by grinding both surfaces of the conductor 10 and the conductor 20 in the Z-direction, both surfaces of each of the insulating material 6, the conductor 10, and the conductor 20 are flattened (Step S45 in FIG. 31), and then dicing is performed (Step S46 in FIG. 31). Here, after the terminals 2 and 3 (protrusions 10a) are ground, the sealing step is not performed again. As a result, the surfaces of the terminals 2 and 3 remain exposed from the insulating material 6.

Subsequently, by performing dicing, a plurality of divided semiconductor chips 1c can be obtained. In the semiconductor chip 1c, a flat surface including the surfaces of the insulating material 6 and the terminals 2, 3, and 4 exposed on the bonding material 4b side with respect to the semiconductor substrate 5 constitutes the main surface S4. A flat surface which is the surface on the opposite side of the main surface S4 of the semiconductor chip 1c (the surface on the bonding material 2b side with respect to the semiconductor substrate 5) and includes the surfaces of the insulating material 6 and the terminals 2 and 3 constitutes the main surface S3. In this manner, the semiconductor device of the present modification example is substantially completed.

In the present modification example, it is possible to obtain effects similar to those of the semiconductor device described with reference to FIGS. 20 to 22. In addition, since there is no insulating material 6 covering the terminals 2 and 3 on the main surface S3, it is possible to reduce the size of the semiconductor device, the cooling effect on the main surface S3 side is enhanced. Further, it is also possible to perform inspection and measurement by bringing the probe into contact with both the main surface S3 side and the main surface S4 side.

Hitherto, although the invention made by the present inventors has been specifically described above based on the embodiments, the present invention is not limited to the above embodiments, and various modifications can be made in a range without departing from the gist thereof.

### INDUSTRIAL APPLICABILITY

The present invention can be widely used in a semiconductor device and a manufacturing method for the same.

### REFERENCE SIGNS LIST

1, 1a to 1c, 1x semiconductor chip
2, 3, 4 terminal
2a source electrode
2b, 3b, 4b, 7 bonding material
2c, 3c, 4c extraction electrode
3a gate electrode
4a drain electrode
5 semiconductor substrate
6 insulating material
8 wiring
9 insulating substrate
10, 20 conductor
10a, 10b protrusion
10c connection portion
41 bonding wire
100, 100a semiconductor module
S1, S2, S3, S4 main surface

1. A semiconductor device comprising:
a semiconductor substrate including a first main surface, a second main surface opposite to the first main surface, and a semiconductor element;
a first terminal connected to a first electrode provided in contact with the first main surface via a first bonding material having conductivity;
a second terminal connected to a second electrode provided in contact with the second main surface via a second bonding material having conductivity, the second terminal being insulated from the first terminal;
an insulating material that seals the semiconductor substrate and a part of each of the first terminal and the second terminal;
a third main surface located on the first bonding material side with respect to the semiconductor substrate, the third main surface exposing the first terminal and the second terminal; and
a fourth main surface opposite to the third main surface,
wherein the second terminal is extracted to the third main surface side by an extraction electrode spaced from a stacked body including the semiconductor substrate, the first electrode, and the first bonding material, and
the first terminal and the second terminal are insulated from each other by the insulating material.

2. The semiconductor device according to claim 1, wherein
a terminal is not exposed on a surface other than the third main surface.

3. The semiconductor device according to claim 1, wherein
the second terminal is exposed on the fourth main surface.

4. The semiconductor device according to claim 1, wherein
a plurality of the first terminals are formed,
each of the plurality of first terminals is connected to each of a plurality of the first electrodes formed in contact with the first main surface via the first bonding material, and
the plurality of first terminals are exposed on the third main surface.

5. The semiconductor device according to claim 1, wherein
a plurality of the second terminals are formed,
each of the plurality of second terminals is connected to each of a plurality of the second electrodes formed in contact with the second main surface via the second bonding material, and
the plurality of second terminals are exposed on the third main surface.

6. The semiconductor device according to claim 5, wherein
the plurality of second terminals are exposed on the fourth main surface.

7. The semiconductor device according to claim 5, wherein
a shape of the first terminal exposed on the third main surface in plan view is substantially rectangular, and
the second terminal exposed on the third main surface extends along one side, two sides, three sides, or four sides of the first terminal in plan view.

8. A manufacturing method for a semiconductor device, the method comprising the steps of:
(a) a step of preparing a semiconductor substrate including a first main surface, a second main surface opposite to the first main surface, and a semiconductor element, a first electrode being in contact with the first main surface, and a second electrode being in contact with the second main surface;
(b) a step of connecting a first conductor to the first electrode via a first bonding material having conductivity;
(c) a step of preparing a second conductor having a first protrusion on a surface;
(d) a step of spacing a stacked body including the semiconductor substrate and the first electrode from the first protrusion and connecting the second electrode to the surface of the second conductor via a second bonding material having conductivity; and
(e) a step of sealing the semiconductor substrate, the first conductor, and the second conductor with an insulating material after the steps (a) to (d),
wherein the semiconductor device includes a third main surface on which a first terminal made of the first conductor and a second terminal made of the second conductor are exposed, and a fourth main surface opposite to the third main surface,
the third main surface is located on the first bonding material side with respect to the semiconductor substrate,
the first terminal and the second terminal are insulated from each other, and
the second terminal is extracted toward the third main surface by the first protrusion.

9. The manufacturing method for a semiconductor device according to claim 8, further comprising
(f) a step of exposing the first conductor and the second conductor from the insulating material on the third main surface by removing a part of the insulating material by grinding, after the step (e).

10. The manufacturing method for a semiconductor device according to claim 9, further comprising:
(b1) a step of preparing the first conductor including a first support portion and a plurality of second protrusions arranged on a surface of the first support portion before the step (b),
wherein, in the step (a), the semiconductor substrate in which a plurality of the first electrodes insulated from each other are in contact with the first main surface is prepared,
in the step (b), each of the plurality of second protrusions is connected to each of the plurality of first electrodes via the first bonding material,
in the step (f), by removing the first support portion and a part of the insulating material by grinding, the plurality of second protrusions spaced from each other and the second conductor are exposed from the insulating material on the third main surface, and
the plurality of second protrusions exposed on the third main surface constitute a plurality of the first terminals insulated from each other.

11. The manufacturing method for a semiconductor device according to claim 8, wherein
in the step (e), the semiconductor substrate, the first conductor, and the second conductor are sealed with the insulating material, excluding a surface of the second conductor forming the fourth main surface.

12. The manufacturing method for a semiconductor device according to claim 9, further comprising
(f1) a step of exposing the second conductor from the insulating material on the fourth main surface by removing a part of the insulating material by grinding, after the step (e).

13. The manufacturing method for a semiconductor device according to claim 8, further comprising
(f2) a step of removing a part of the insulating material and a part of the second conductor by grinding after the step (e),
wherein, in the step (a), the semiconductor substrate in which a plurality of the second electrodes insulated from each other are in contact with the second main surface is prepared,
in the step (c), the second conductor including a second support portion, a plurality of third protrusions formed on a surface of the second support portion, and a plurality of the first protrusions formed on the surface of the second support portion via the plurality of third protrusions is prepared,
in the step (d), the stacked body including the plurality of second electrodes is spaced from the plurality of first protrusions, and each of the plurality of second electrodes is connected to a surface of the plurality of third protrusions which is the surface of the second conductor via the second bonding material,
in the step (f2), by removing the part of the insulating material and the second support that is the part of the second conductor by grinding, the plurality of third protrusions spaced from each other are exposed from the insulating material on the fourth main surface, and
the plurality of third protrusions exposed on the fourth main surface constitute the plurality of second terminals insulated from each other.

14. The manufacturing method for a semiconductor device according to claim 13, further comprising
(f3) a step of sealing the plurality of second terminals on the fourth main surface after the step (f2).
